(19) United States
(12) Patent Application Publication
(10) Pub. No.: US 2023/0193435 A1
(43) Pub. Date: Jun. 22, 2023

(54) HIGH-ENTROPY ALLOY FILM AND MANUFACTURING METHOD THEREOF

(71) Applicant: MING CHI UNIVERSITY OF TECHNOLOGY, New Taipei (TW)

(72) Inventors: Jyh-Wei Lee, New Taipei (TW); Bih-Show Lou, New Taipei (TW); Yung-Chin Yang, New Taipei (TW); Hsin Chao, New Taipei (TW)

(21) Appl. No.: 18/097,567

(22) Filed: Jan. 17, 2023

Related U.S. Application Data
(62) Division of application No. 17/368,987, filed on Jul. 7, 2021.

(30) Foreign Application Priority Data
Feb. 17, 2021 (TW) 110105287

(51) Int. Cl. C22C 30/00; C23C 14/35; C23C 14/16; C22C 27/02

(52) U.S. Cl. CPC C22C 30/00; C22C 27/02; C23C 14/16; C23C 14/35; C30B 29/06

(57) ABSTRACT

A high-entropy alloy film, the composition of which includes titanium, zirconium, niobium, tantalum and iron. The high-entropy alloy film is made with a combination of elements with high biocompatibility, and its formation of non-crystalline structure is further improved by adding iron. Furthermore, as the content of titanium in the high-entropy alloy film is adjusted, the microstructure, mechanical properties, and corrosion resistance of the high-entropy alloy film is changed as well.

### REFERENCE TO RELATED APPLICATIONS

This is a divisional application of patent application Ser. No. 17/368,987, filed on Jul. 7, 2021, which claims the priority benefit of Taiwan Patent Application No. 110105287, filed on Feb. 17, 2021. The entirety of each of the above-mentioned patent applications is hereby incorporated by reference herein and made a part of this specification.

### BACKGROUND OF THE INVENTION

### 1. Field of the Invention

The present disclosure relates to the field of alloy materials, and in particular to a high-entropy alloy film and its manufacturing method.

### 2. Description of the Related Art

Alloy materials have had a wide-ranging impact on civilization for centuries, not only creating the current industrial development situation, but also significantly improving the standard of living. Conventional alloy materials are mostly made up of a major metal element, combined with a small amount of other elements, and then produced according to a specific process method. Conventional alloy materials are typically doped at a higher proportion. However, the higher the doping of the elements, the more easily the synthesized compound becomes brittle.

Until about 2004, the concept of high-entropy alloy was proposed, and it was regarded as having the potential to break through the performance of traditional alloys. High-entropy alloys are made by mixing about 5 or more metals at a ratio of 5% to 35%. This ration can greatly increase the possibility of the arrangement of atoms of different elements, produce high-entropy effects, have a high hardness and high strength, have increased wear resistance, and improved high temperature resistance. Therefore, the applicability of high-entropy alloys is currently attracting attention, and have numerous applications that extend to the field of coating.

Further, many different configurations of high-entropy alloy systems can be used in different fields in response to their different characteristics. Therefore, designing a suitable high-entropy alloy system according to needs is a very important research direction in this field. For example, to meet medical-related requirements, the high-entropy alloy material needs to be prepared for biocompatibility, high corrosion resistance, good mechanical properties, and other properties and characteristics.

### BRIEF SUMMARY OF THE INVENTION

This summary of the invention aims to provide a simplified summary of the invention so that readers have a basic understanding of the invention. This summary of the invention is not a complete overview of the invention, and its intention is not to point out important or key elements of the embodiments of the invention or to define the scope of the invention.

In view of the content mentioned in the prior art, the inventors of the present invention have many years of experience in manufacturing and development of related industries, and provides a high-entropy alloy film, the composition of which includes titanium, zirconium, niobium, tantalum and iron. The high-entropy alloy film is made with a combination of elements with high biocompatibility, and at the same time, by adding an iron element, the amorphous forming ability is improved and the cost is reduced. Further, the present invention provides an adjustable high-entropy alloy film. The content of titanium in the entropy alloy film further changes the microstructure, mechanical properties, corrosion resistance and biocompatibility of the high-entropy alloy film.

Accordingly, in some aspects of the present invention, a high-entropy alloy film is provided, the composition of which includes titanium, zirconium, niobium, tantalum, and iron.

According to some embodiments of the present invention, the individual contents of titanium, zirconium, niobium, tantalum, and iron are all between 5 and 35 atomic percent (at.%).

According to some embodiments of the present invention, the content of titanium is from 16.3 to 17.5 atomic percent (at.%).

According to some embodiments of the present invention, the content of titanium is from 19.3 to 20.1 atomic percent (at.%).

According to some embodiments of the present invention, the content of titanium is from 25 to 26 atomic percent (at.%).

In still other aspects of the present invention, a method for manufacturing a high-entropy alloy thin film is provided which includes providing at least one high-entropy alloy target material. The high-entropy alloy target material includes titanium, zirconium, niobium, tantalum, and iron. The individual contents of titanium, zirconium, niobium, tantalum, and iron are all between 5 and 35 atomic percent (at.%). A physical vapor deposition method using the high-entropy alloy target is adapted to deposit on at least one surface of a substrate and the high-entropy alloy film is formed on the surface of the substrate.

According to some embodiments of the present invention, the physical vapor deposition method is an evaporation method, a magnetron sputtering method, an ion plating method, a cathodic arc coating method, a pulse laser deposition method, or an atomic layer deposition method.

According to some embodiments of the present invention, the substrate is a commercially pure titanium (cp-Ti) or a P-type (100) single crystal silicon substrate.

### BRIEF DESCRIPTION OF THE DRAWINGS

In order to make the above and other objects, features, advantages, and embodiments of the present invention easier to understand, the description of the accompanying drawings is as follows:

FIG. 1 is a flow chart illustrating a method for manufacturing a high-entropy alloy film according to an embodiment of the present invention;

FIG. 2 is an X-ray diffraction spectrum diagram according to an embodiment of the present invention;

FIG. 3A is a scanning electron microscope image of the cross-sectional structure according to an embodiment of the present invention;

FIG. 3B is a scanning electron microscope image of the cross-sectional structure according to an embodiment of the present invention;

FIG. 3C is a scanning electron microscope image of the cross-sectional structure according to an embodiment of the present invention;

FIG. 3D is a scanning electron microscope image of the cross-sectional structure according to an embodiment of the present invention;

FIG. 3E is a scanning electron microscope image of the cross-sectional structure according to an embodiment of the present invention;

FIG. 3F is a scanning electron microscope image of the cross-sectional structure according to an embodiment of the present invention;

FIG. 4 is a potentiodynamic polarization curve diagram according to an embodiment of the present invention (presented in color);

FIG. 5 is a histogram of the number of survival cells according to an embodiment of the present invention;

FIG. 6A is a stained image of a muscle tissue specimen according to an embodiment of the present invention (presented in color);

FIG. 6B is a stained image of a muscle tissue specimen according to an embodiment of the present invention (presented in color);

FIG. 6C is a stained image of a muscle tissue specimen according to an embodiment of the present invention (presented in color);

FIG. 6D is a stained image of a muscle tissue specimen according to an embodiment of the present invention (presented in color); and

FIG. 7 is an external view of the test piece according to an embodiment of the present invention (presented as a photo).

According to the usual operating method, the various features and elements in the figures are not drawn to actual scale, and the drawing methods are used to present the specific features and elements related to the present invention in the best way. In addition, in different drawings, the same or similar element symbols are used to refer to similar elements and components.

### DETAILED DESCRIPTION OF THE INVENTION

In order to make the description of the present invention more detailed and complete, the following provides an illustrative description for the implementation aspects and specific embodiments of the present invention, but this is not the only way to implement or use the specific embodiments of the present invention. In the scope of this specification and the appended patent application, unless the context indicates otherwise, “a” and “the” can also be interpreted as plurals. In addition, in the scope of this specification and the attached patent application, unless otherwise stated, “installed on something” can be regarded as directly or indirectly in contact with the surface of something by attaching or other forms. The definition of the surface should be judged based on the semantics of the preceding and following/paragraphs of the description and the general knowledge of the field to which this description belongs.

Although the numerical ranges and parameters used to define the present invention are approximate numerical values, the relevant numerical values in the specific embodiments have been presented here as accurately as possible. However, any value inherently inevitably contains standard deviations due to individual test methods. Here, “about” usually means that the actual value is within plus or minus 10%, 5%, 1%, or 0.5% of a specific value or a range. Alternatively, the term “about” means that the actual value falls within the acceptable standard error of the average value, which is determined by those who have ordinary knowledge in the field of the present invention. Therefore, unless otherwise stated to the contrary, the numerical parameters disclosed in this specification and the accompanying patent scope are approximate values and can be changed according to requirements. At least these numerical parameters should be understood as the indicated effective number of digits and the value obtained by applying the general carry method.

### Embodiments

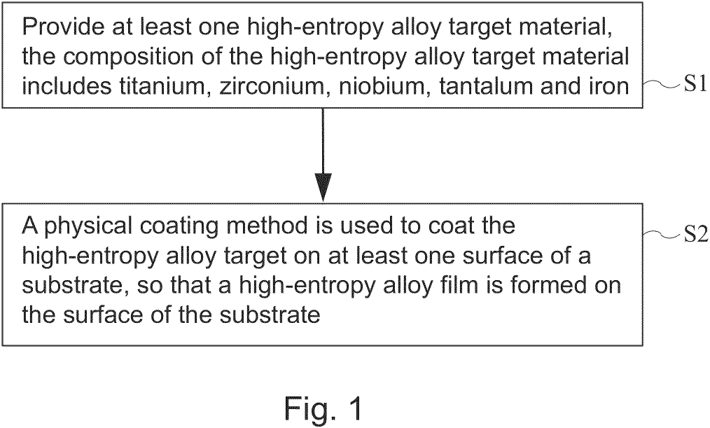

The embodiments of the present invention aim to provide a high-entropy alloy film and a manufacturing method thereof. For this embodiment, the technical spirit of the present invention can be further understood according to the flowchart shown in FIG. 1. Please refer to FIG. 1. The method for manufacturing a high-entropy alloy of this embodiment includes processes S1 to S2. Process S1 is to provide at least one high-entropy alloy target material, the composition of the high-entropy alloy target material includes titanium (Ti), zirconium (Zr), niobium (Nb), tantalum (Ta) and iron (Fe). The individual contents of titanium, zirconium, niobium, tantalum, and iron are all between 5 and 35 atomic percent (at.%). In process S2, a physical vapor deposition method using the high-entropy alloy target to coat on at least one surface of a substrate, so that a high-entropy alloy film is formed on the surface of the substrate.

In process S1, vacuum arc melting or powder metallurgy can be used to make the high-entropy alloy target using the five pure elements of titanium, zirconium, niobium, tantalum, and iron according to proportions. The alloy target is a TiZrNbTaFe high-entropy alloy target. The individual contents of titanium, zirconium, niobium, tantalum, and iron in the composition are all between 5 and 35 atomic percent (at.%). However, the preparation process of the TiZrNbTaFe high-entropy alloy target and the processing method after preparation (for example, conventional technical content such as grinding and leveling after solidification) are not limited by the present invention.

In the process S2, first, a commercially pure titanium (cp-Ti), or Ti alloy, or 316 L stainless steel, or a P-type (100) single crystal silicon substrate is selected as the substrate. Next, the TiZrNbTaFe high-entropy alloy target produced in process S1 is coated on the surface of the substrate by a physical vapor deposition method, wherein the physical vapor deposition method can be evaporation deposition, magnetron sputtering, an ion plating method, a cathodic arc coating method, a pulse laser deposition method, or an atomic layer deposition method. Preferably, the physical vapor deposition method is a magnetron sputtering method. More preferably, the magnetron sputtering method is high-power impulse magnetron sputtering (HiPIMS) or high-power pulsed magnetron sputtering (HPPMS). Accordingly, in this embodiment, the TiZrNbTaFe high-entropy alloy target and a pure titanium target are co-deposited on the substrate by a high-power impulse magnetron sputtering system. During deposition, the operating power of the TiZrNbTaFe high-entropy alloy target is fixed at 300 W, and the operating power of the titanium target is set to 0 W, 25 W, 50 W, 75 W, 100 W, 125 W, so as to obtain six kinds of high-entropy alloy films with different titanium contents. Alternatively, those with ordinary knowledge in the technical field to which this case belongs can also directly operate with six TiZrNbTaFe high-entropy alloy targets with a fixed metal content. In addition, the deposition time of this process is from 70 to 90 minutes. Preferably, it is 80 minutes. However, the detailed parameter settings are not limited by the present invention.

For the six kinds of high-entropy alloy films made by the above-mentioned manufacturing method, the composition analysis was further performed with a field emission electron probe microanalyzer (FE-EPMA). The composition after the analysis is shown in Table 1 below. The composition of the six film samples obtained includes titanium, zirconium, niobium, tantalum, iron, and oxygen. The individual contents of titanium, zirconium, niobium, tantalum, and iron are all between 5 to 35 atomic percent (at.%) The oxygen content is between 5 to 7 atomic percent (at.%), which is obtained due to the contamination from the deposition system or from the target. Furthermore, the above-mentioned samples 1 to 6 have six kinds of titanium content between approximately 16.3 to 26 atomic percent depending on the operating power of the titanium target. Alternatively, the above samples 1 to 6 all meet the definition of high-entropy alloys, that is, the change in entropy per mole (ΔS) is greater than 1.5R.

TABLE 1

| Sample (Ti target power) | Composition (at. %) | | | | | | ΔS |
|---|---|---|---|---|---|---|---|
| | Ti | Zr | Nb | Ta | Fe | O | |
| 1 (0 W) | 16.9 ± 0.6 | 12.7 ± 0.2 | 22.2 ±0.4 | 20.2 ± 0.2 | 21.8 ±0.04 | 6.1 ± 0.3 | 1.59R |
| 2 (25 W) | 17.3 ± 0.5 | 14.5 ± 0.2 | 22.2 ± 0.4 | 18.7 ± 0.7 | 20.8 ±0.356 | 6.8 ± 0.7 | 1.60R |
| 3 (50 W) | 18.1 ± 1.1 | 13.3 ± 0.4 | 22.0 ± 0.5 | 18.9 ± 0.8 | 21.4 ±0.6 | 5.9 ± 0.1 | 1.60R |
| 4 (75 W) | 19.7 ± 0.4 | 13.7 ± 0.2 | 21.8 ± 0.4 | 18.3 ± 0.6 | 20.4 ±0.3 | 5.9 ± 0.5 | 1.60R |
| 5 (100 W) | 21.8 ± 0.4 | 12.6 ± 0.1 | 21.1 ± 0.2 | 17.9 ± 0.3 | 20.2 ±0.4 | 6.2 ± 0.6 | 1.59R |
| 6 (125 W) | 25.5 ± 0.5 | 11.8 ± 0.1 | 19.6 ± 0.2 | 17.4 ± 0.3 | 19.3 ±0.2 | 6.1 ± 0.2 | 1.58R |

Next, the present invention further provides X-ray diffraction analysis, cross-sectional microstructure analysis, mechanical property analysis, corrosion resistance analysis, and biocompatibility analysis performed on the high-entropy alloy films of samples 1 to 6. Please refer to the tables and drawings of the present invention for a more comprehensive understanding of the technical features and effects of the present invention.

### X-Ray Diffraction Analysis

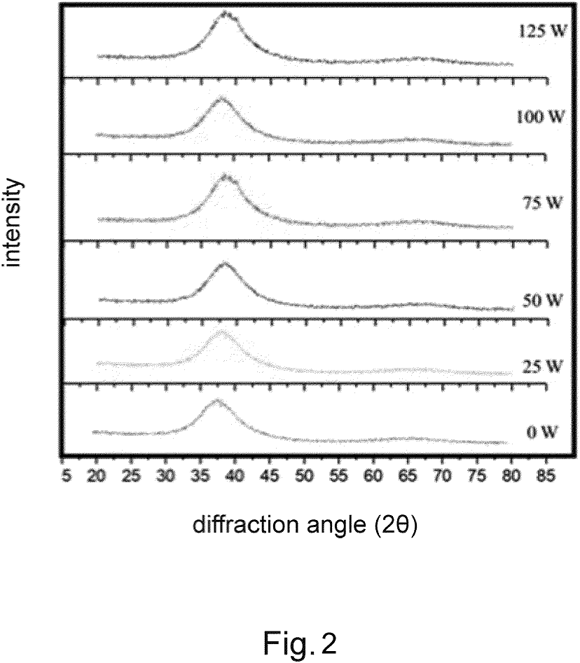

X-ray diffraction analysis mainly uses accelerated electrons to hit a metal target to generate X-rays and irradiate X-rays on the surface of the material. Because different crystal structures have different crystal plane spacing, and only when the X-ray incident angle meets Bragg’s law, constructive interference can be generated, and the detector can receive a strong diffracted beam signal. Accordingly, different materials or different structures have different angles of constructive interference. Refer to FIG. 2, which is the X-ray diffraction pattern of samples 1 to 6 above, where the X-axis refers to the diffraction angle (2θ), and the Y-axis refers to the intensity. According to FIG. 2, it can be understood that the high-entropy alloy films of samples 1 to 6 have broad diffraction peaks between 30 and 45 degrees of diffraction angle (2θ), and no crystalline characteristic peaks are found. Therefore, samples 1 to 6 high-entropy alloy films are all amorphous structures.

### Cross-Sectional Microstructure Analysis

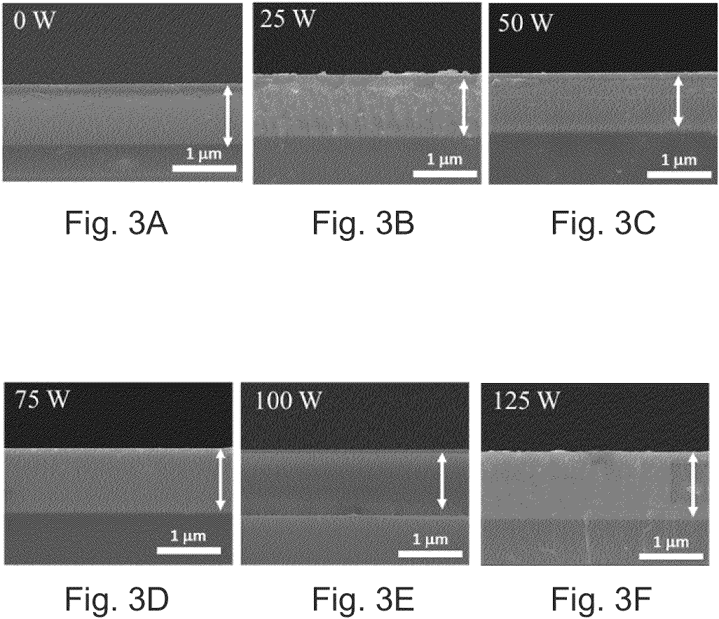

At this stage, the scanning electron microscope (SEM) is used to observe the cross-sectional microstructure of the above-mentioned samples 1 to 6, and the images obtained are as shown in FIGS. 3A~3F, showing a common amorphous film. Specifically, the thickness of the high-entropy alloy film increases as the operating power of the titanium target increases. More specifically, the thickness of sample 1 is 1.10 µm, and the thickness of sample 6 is 1.29 µm.

### Mechanical Property Analysis

At this stage, a nanoindenter is used to measure the mechanical properties of the high-entropy alloy films of the above samples 1 to 6. The technique mainly measures the elastic modulus (E) and hardness (H) of the samples by nano-sized probes (both units are billion Pascals (GPa)), and obtain the plastic index (hardness/elastic modulus, H/E) by calculation, which can be regarded as an index of the wear resistance of the material. The mechanical quality test results of the above samples 1 to 6 are shown in Table 2 below. It can be further understood that as the content of titanium contained in the high-entropy alloy film increases, the hardness of the film decreases. Therefore, sample 6 (the operating power of the titanium target is 125 W) has the best wear resistance compared to other samples.

TABLE 2

| Sample (Ti target power) | 1 (0 W) | 2 (25 W) | 3 (50 W) | 4 (75 W) | 5 (100 W) | 6 (125 W) |
|---|---|---|---|---|---|---|
| Hardness (GPa) | 9.1±0.5 | 9.0±0.1 | 8.9±0.1 | 8.6±0.3 | 8.4±0.3 | 8.4±0.5 |
| Elastic modulus (GPa) | 135.0±4.9 | 134.0±2.7 | 128.7±3.0 | 128.2±2.8 | 128.2±4.4 | 127.4±1.5 |
| H/E | 0.0675 | 0.0673 | 0.0656 | 0.0673 | 0.0656 | 0.0702 |

### Corrosion Resistance Analysis

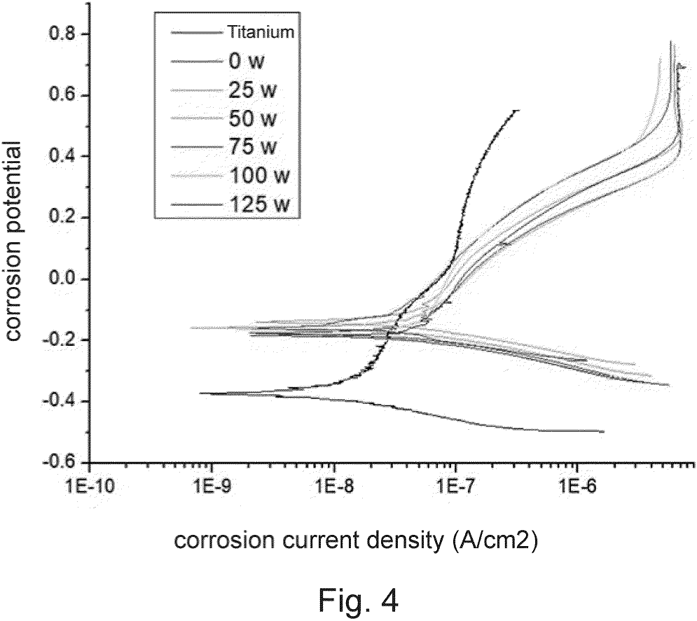

In this stage, the corrosion resistance of the test piece coated with the high-entropy alloy film of the above samples 1 to 6 in Ringer solution is measured by a potentiostat, and the commercial pure titanium substrate is used as the control test piece for comparison. The potential value or current value recorded during the experiment can be used to obtain a potentiodynamic polarization curve and analyze corrosion resistance. Refer to FIG. 4, which shows the potentiodynamic polarization curves of the above samples 1 to 6 and the control group, and refer to Table 3 below, which shows the corrosion resistance data of the above samples 1 to 6. It can be further understood that the test strips coated with the above samples 1 to 6 have higher corrosion potential (Ecorr, unit: V) than the control test strips. Among them, sample 4 (the operating power of the titanium target is 75 W) has a very low corrosion current density (unit: A/cm2) and the highest corrosion resistance (unit: Ωcm2). According to this, sample 4 (the operating power of the titanium target is 75 W) has the best corrosion resistance compared to the other samples.

TABLE 3

| Sample # | E_{corr}(v) | Icorr (A/cm²) | Rp(Ωcm²) |
|---|---|---|---|
| cp-Ti | -324.06 | 1.35x10⁻⁹ | 1.43x10⁶ |
| 1 (0 W) | -172.55 | 2.91x10⁻⁸ | 4.48x10⁵ |
| 2 (25 W) | -155.10 | 2.70x10⁻⁸ | 5.04x10⁵ |
| 3 (50 W) | -134.85 | 2.46x10⁻⁸ | 5.5x10⁵ |
| 4 (75 W) | -160.40 | 1.83x10⁻⁸ | 8.05x10⁵ |
| 5 (100 W) | -177.30 | 2.29x10⁻⁸ | 5.53x10⁵ |
| 6 (125 W) | -181.40 | 3.68x10⁻⁸ | 4.42x10⁵ |

### Cell Experiment

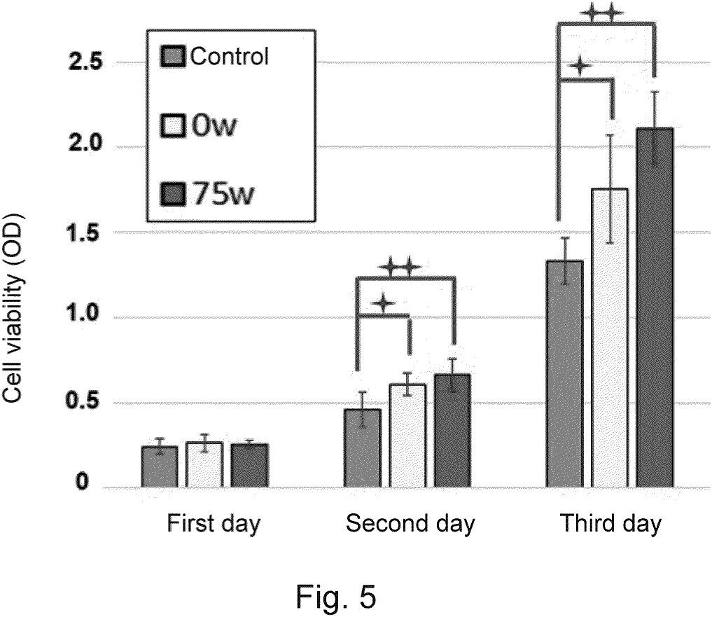

In this stage, the present invention selects sample 4 (the operating power of the titanium target is 75 W) with the best corrosion resistance in the above-mentioned corrosion resistance analysis, sample 1 (the operating power of the titanium target is 0 W), as well as commercial pure titanium substrates, and osteoblast-like cells MG-63 were used for cell viability analysis. By culturing MG-63 cells on the test piece coated with the above sample 4 and sample 1, and a commercial pure titanium substrate (as a control group), and observing the number of cells surviving after 1, 3, and 5 days of culture, and evaluate the biocompatibility of the experimental samples. Refer to FIG. 5, which is a histogram of the number of cell survival further drawn based on the experimental content at this stage. According to FIG. 5, it can be understood that the test strips coated with the above samples 1 and 4 have substantially higher values than the control group. The test piece coated with the above sample 4 has a higher cell survival rate than the one coated with the sample 1.

### Animal Experiment

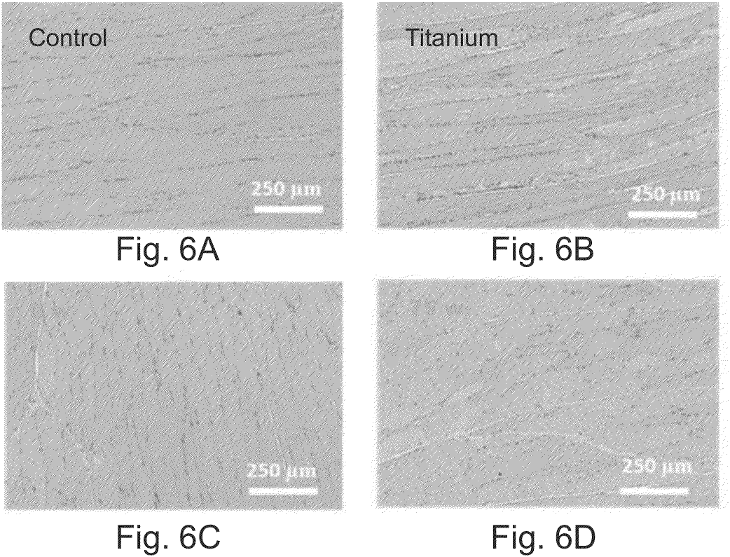

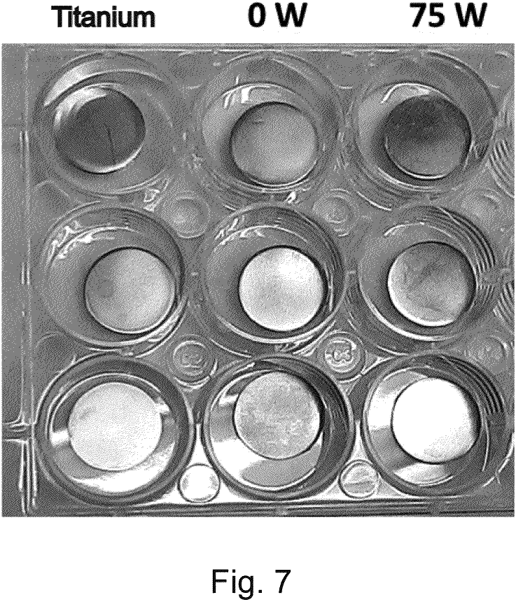

In this stage, the same sample group as the cell experiment is selected, and then the animal experiment of subcutaneous implantation in rats is further carried out. First, the diameter of the test piece used is 15 mm and the thickness is 1 mm. The test piece was coated with the above-mentioned sample 1 (operating power of titanium target is 0 W) and sample 4 (operating power of titanium target is 75 W), and experiments were carried out separately with commercial pure titanium substrates with the same geometric parameters. The test pieces were implanted under the skin of the rats and at 1, 4, and 12 weeks they were taken out and observed. Then, the muscle tissue specimens in contact with the test pieces were collected, and the tissue sections were stained with hematoxylin-eosin to observe their relative inflammatory state compared to a control group when the test piece was not implanted. Refer to FIGS. 6A-6D, which are stained images of the muscle tissue specimens in contact with the different test strips after being taken out from the rat subcutaneously at the 12th week (the control group is the case where the test strip is not implanted). Also refer to FIG. 7, which shows the appearance of test piece. According to the above results, it can be understood that none of the specimens coated with the above-mentioned sample 1 (operating power of the titanium target material is 0 W) and sample 4 (operating power of the titanium target material is 75 W) caused inflammation, and there was no inflammatory reaction after being taken out.

According to the content of the above-mentioned embodiments, it can be understood that through the implementation of the present invention, not only a high-entropy alloy film with good biocompatibility can be made, but also the content of the titanium component can be adjusted to obtain excellent mechanical properties and corrosion resistance. In addition, by adding iron elements, not only can the manufacturing cost be reduced, but also the ability to produce amorphous structures can be improved.

Although the present invention has been disclosed in the above embodiments, it is not intended to limit the present invention. Anyone with ordinary knowledge in the technical field can make some changes and modifications without departing from the spirit and scope of the present invention. Therefore, the scope of protection of the present invention shall be based on what is defined by the attached patent application scope.

What is claimed is:

1. A method for manufacturing a high-entropy alloy thin film, including:
providing at least one high-entropy alloy target material, wherein a composition of the high-entropy alloy target material includes titanium, zirconium, niobium, tantalum, and iron, and wherein individual contents of titanium, zirconium, niobium, tantalum, and iron are all between 5 and 35 atomic percent (at.%); and
depositing the at least one high-entropy alloy target material on at least one surface of a substrate using a physical vapor deposition method so as to form a high-entropy alloy thin film on the at least one surface of the substrate.

2. The method for manufacturing a high-entropy alloy thin film according to claim 1, wherein the physical vapor deposition method is an evaporation method, a magnetron sputtering method, an ion plating method, a cathodic arc coating method, a pulse laser deposition method, or an atomic layer deposition method.

3. The method for manufacturing a high-entropy alloy thin film according to claim 1, wherein the substrate is a commercially pure titanium (cp-Ti) substrate, a Ti alloy substrate, a 316 L stainless steel substrate, or a P-type single crystal silicon substrate.
